(19) United States
(12) Patent Application Publication
(10) Pub. No.: US 2025/0371232 A1
(43) Pub. Date: Dec. 4, 2025

(54) MACHINE LEARNING BASED ALGORITHM FOR PREDICTION

(71) Applicants: Tito Busani, Albuquerque, NM (US); Manel Martinez-Ramon, Albuquerque, NM (US); Rahul Jaiswal, Albuquerque, NM (US); Abu Shami Md Md Zadid Shifat, Albuquerque, NM (US)

(72) Inventors: Tito Busani, Albuquerque, NM (US); Manel Martinez-Ramon, Albuquerque, NM (US); Rahul Jaiswal, Albuquerque, NM (US); Abu Shami Md Md Zadid Shifat, Albuquerque, NM (US)

(73) Assignee: UNM Rainforest Innovations, Albuquerque, NM (US)

(21) Appl. No.: 19/183,724

(22) Filed: Apr. 18, 2025

Related U.S. Application Data
(60) Provisional application No. 63/635,623, filed on Apr. 18, 2024.

(51) Int. Cl. G06F 30/3308

(52) U.S. Cl. CPC G06F 30/3308

(57) ABSTRACT

An machine learning (ML)-based algorithm used for prediction to calibrate simulation models for semiconductor devices. More than one simulation model for a semiconductor device for predicting more than one performance metric is contemplated. According to one embodiment, the predictive model using ML can be used specifically to estimate an etching profile and vertical sidewall angle.

### RELATED APPLICATIONS

This application claims the benefit of U.S. Provisional 63/635,623 filed Apr. 18, 2024, the disclosure of which is hereby incorporated by reference in its entirety.

### FIELD OF THE INVENTION

The invention relates generally to algorithms used for prediction. More specifically, the invention relates to a machine learning based algorithm for prediction used to calibrate simulation models for semiconductor devices.

### BACKGROUND OF THE INVENTION

Semiconductors are the powerful force behind a variety of technological applications, from transportation, medical devices, communication systems, and defense.

Semiconductors are a crucial component in electronics, enabling the development of advanced technologies and devices that have transformed many aspects of life. For example, in the computing industry microprocessors and memory chips are produced that are the primary components in computers, servers, and data centers.

Semiconductors are also importance in the communication industry that includes cell phones, satellite systems, and network equipment. Semiconductors are used in power management applications, automotive manufacturing, and autonomous vehicles.

Semiconductor device optimization using computer based prototyping techniques like simulation or machine learning digital twins can be time and resource efficient compared to the conventional strategy of iterating over device design variations by fabricating the actual device. However, simulation models require perfect calibration of material parameters for the model to represent a particular semiconductor device. This calibration process itself can require characterization information of the device and its precursors and extensive expert knowledge of non-characterizable parameters and their tuning.

Turning to a particular embodiment where the method for prediction may be implemented is related to the process control of the etching process of materials, which is extremely difficult to optimize and prototype. Instead, the process control is typically controlled by the conventional hit and trial approach. A tight control of this process would greatly benefit potential device applications, particularly those using Nitrades, ceramics, and oxides since many of these materials are ideal candidates for piezoelectric applications and for micro-electromechanical system (MEMS) devices.

What is needed is an algorithm used for prediction to calibrate simulation models for semiconductor devices. The invention satisfies this need.

### BRIEF SUMMARY OF THE INVENTION

The invention is directed to an algorithm that is machine learning based that is used to calibrate simulation models for semiconductor devices. The algorithm is a method performed by any system, apparatus, or device.

The algorithm is based on the hypothesis that machine learning (ML) models can learn from a minimal data set and can try to predict a target value by interpolating or extrapolating the training data points.

An advantage of the invention is that use of the algorithm rapidly accelerates the time to prototype a device using simulations (while reducing the computational and man-hours resources) and can even allow data generation from calibrated simulation models to be used as training data for developing digital twins of the device (ML models to prototype device designs).

Another advantage of the invention is that it is directed to calibrating multiple simulation models for a device using minimal characterization data and ML-based prediction models.

Another advantage of the invention is that it performs calibration of more than one simulation model for a semiconductor device for predicting more than one performance metric.

The predictive model using ML can be used specifically to estimate an etching profile and vertical sidewall angle as well as other parameters before starting the actual process in clean-room, saving time, material, and man-power resources. It is shown that a predictive model using ML can estimate an etching rate and to predict the verticality of the sidewall angle with more than 90% accuracy.

Yet another advantage is that the invention provides a system, apparatus, device, method and a predictive model using ML to predict the etching characteristics of materials, especially Nitrades, ceramics and oxides as well as the etching profile of AlScN

According to a particular embodiment, process parameters are used as prediction input, Gaussian process regression (GPR) is used, and the quantitative measure of uncertainty in every prediction is estimated.

It is contemplated that algorithm according to the invention is accessed through a computing device. To facilitate greater mobility, the computing device may be handheld and include any small-sized computing device including a display interface. Examples of such devices include a personal digital assistant (PDA), smart hand-held computing device, cellular telephone, or a laptop or netbook computer, handheld console or MP3 player, tablet, or similar hand held computer device.

It is contemplated that the computing device may use the Internet or any other system of interconnected computer networks including cloud computing networks. Additionally, the system and methods may be accessed through a network that is wired or wireless.

The described embodiments are to be considered in all respects only as illustrative and not restrictive, and the scope of the invention is not limited to the foregoing description. Those of skill in the art will recognize changes, substitutions and other modifications that will nonetheless come within the scope of the invention and range of the claims.

### DESCRIPTION OF THE DRAWINGS

The preferred embodiments of the invention will be described in conjunction with the appended drawing provided to illustrate and not to the limit the invention, where like designations denote like elements, and in which:

FIG. 1 illustrates a flow chart for an algorithm used for prediction according to the invention;

FIG. 2 illustrates a table of training data points (features and target parameters);

FIG. 3 illustrates a table of validation data points (features and target parameters);

FIG. 4 illustrates a table of actual and measured predicted values for an etching rate;

FIG. 5 illustrates a table of actual and measured predicted values for a vertical sidewall angle;

FIG. 6 illustrates exemplary computing components of any system, apparatus, or device that may be configured to implement the methods according to the invention.

### DETAILED DESCRIPTION OF THE INVENTION

Although a number of embodiments of the invention will be described in the following, it is understood that these embodiments are presented by way of example only, not limitation. The detailed description of the exemplary embodiments of the invention should not be construed to limit the scope or breadth of the invention.

Therefore, specific structural and functional details disclosed herein are not to be interpreted as limiting, but merely as a representative basis for teaching one skilled in the art to variously employ the present invention in virtually any appropriately detailed method, structure or system. Further, the terms and phrases used herein are not intended to be limiting, but rather to provide an understandable description of the invention.

The invention is directed to a hybrid method to calibrate multiple simulation models for a device using minimal characterization data and machine learning (ML) based prediction models.

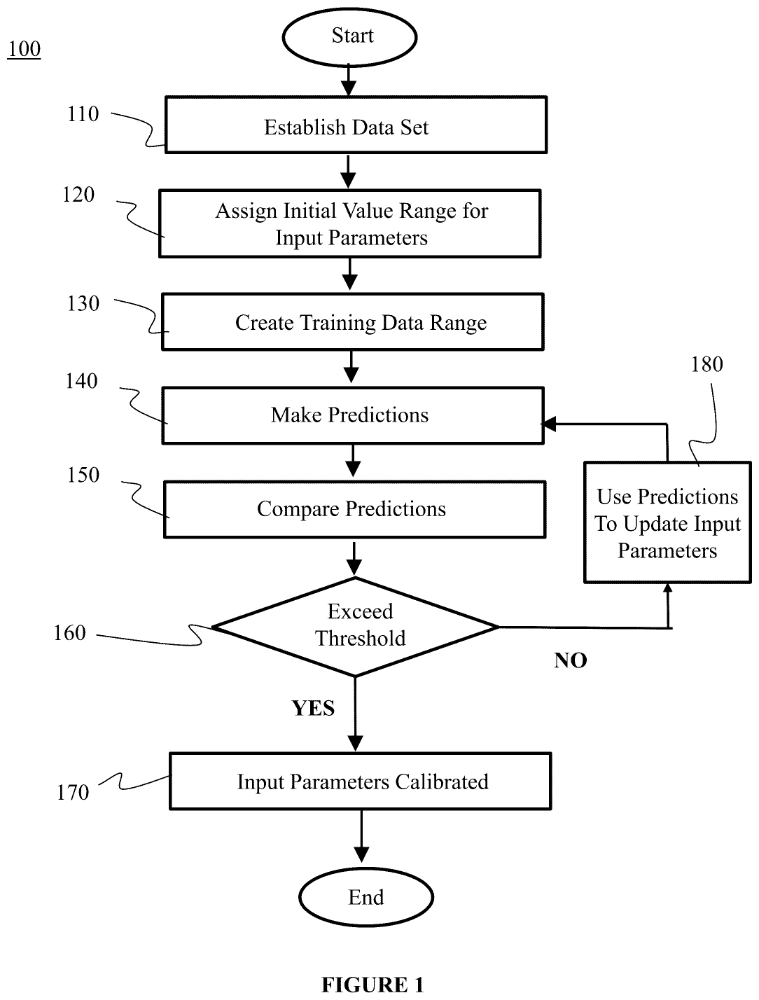

The algorithm is a method performed by any system, apparatus, or device. A flow chart of steps 100 is shown in FIG. 1. At step 110, a data set for different optical and electrical characteristics of a device are established by performing characterization on the device—whose simulation models need calibration—and its precursors.

At step 120, an initial value range—from literature or provided by the device manufacturer—for every simulation input parameter that needs to be calibrated is assigned. It should be noted that parameters that are known with absolute values—for example, measured data or data provided by the manufacturer—is not part of the calibration.

At step 130, a training data range for a machine learning model is created using the uncalibrated simulation model. At step 140, predictions are made using the initial value range of input data. At step 150, each of the predictions are compared against measurements to check the accuracy exceeds a minimal threshold.

If, at step 160, the accuracy reaches the minimal threshold, then the input parameters of that particular prediction are considered calibrated at step 170. Otherwise, at step 180, the initial parameters are updated with the best prediction data and iteratively repeated until accuracy reached the minimal threshold and the input parameters are considered calibrated.

According to one embodiment, a photovoltaic device is chosen where optical and electrical simulation models of an industrially manufactured silicon solar cell are calibrated and the simulated device performance is compared with the measurement data from the physical device. The photovoltaic device is a piezoelectric thin-film material aluminum scandium nitride (AIScN).

A Gaussian process regression (GPR) is used to predict the characteristics of an etching profile of the AIScN, with process parameters, used as prediction input. This ML-based algorithm not only provides the prediction, but also estimates the quantitative measure of uncertainty in every prediction.

GPR is used as the ML methodology because of at least two reasons: One, most relationships between semiconductor device, material, and performance parameters are nonlinear in nature, and because GPR's can address those linearities using kernel functions and GPR's calculate a kernel covariance matrix, which provides the knowledge of variance (or confidence) within every prediction of the ML model.

Features of dry etching were selected as input features for the ML-based algorithm to predict etching rate and vertical sidewall angle. Here, six features were selected as input features and it should be noted that the features selected do not need to be correlated with the two parameters—etching rate and vertical sidewall angle—selected for as the prediction targets.

Specifically, a kernel based regression approach maps these input features from a lower dimensional space (e.g., a 2-dimensional space) to a higher dimensional space, since correlations can be found that exist in between these features in the higher dimensional space. According to a particular example, Matern Kernel is used as the covariance function in the Gaussian process regression, with a smoothening parameter of 1.5. A constant mean is used with a Gaussian Likelihood function.

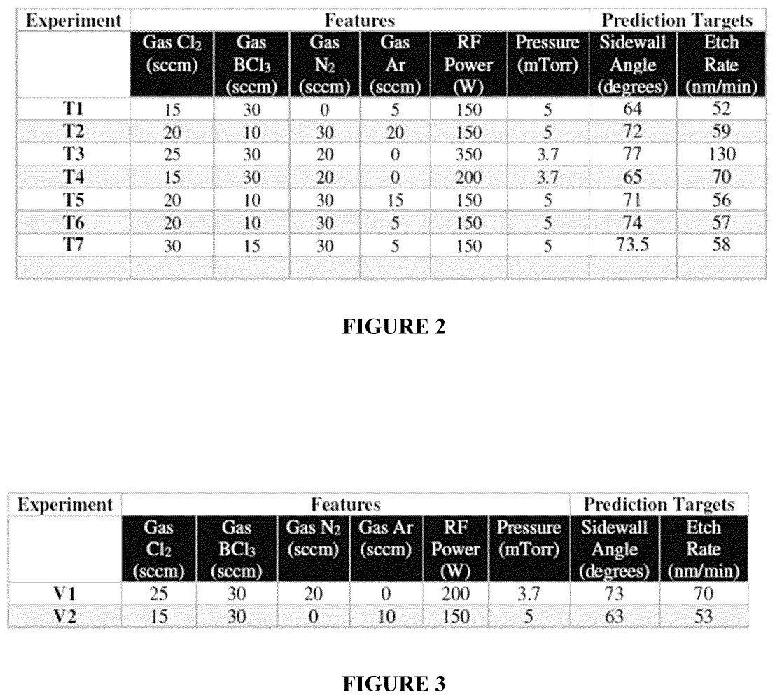

As shown in FIG. 2, a total of 7 data points (experimental recipes) were used to train the model and the model was verified with 2 recipes shown in FIG. 3.

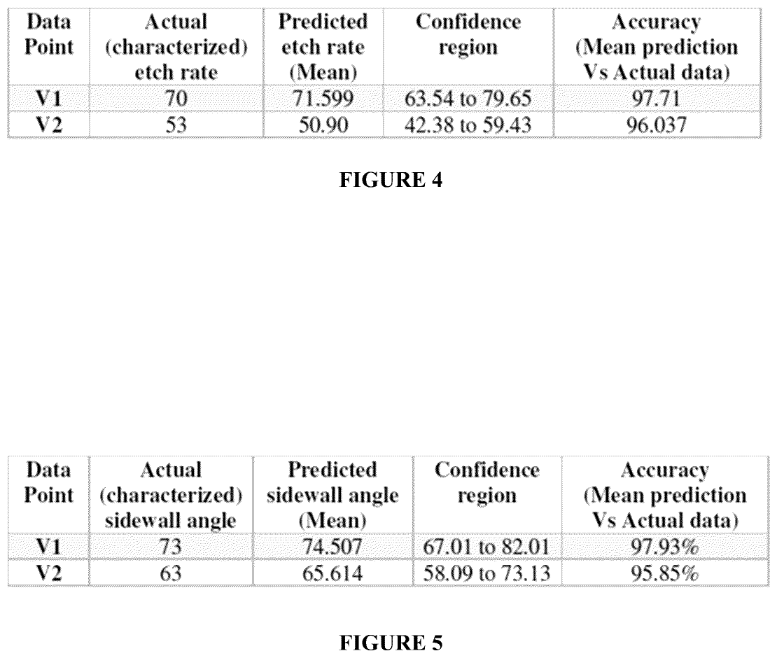

FIG. 4 and FIG. 5 compare the predicted and actual (characterized) data for the 2 recipes used for verifying the ML-based algorithm accuracy. As shown for all 4 cases (2 data points and 2 predictions, vertical sidewall angles and etch rates), the accuracy was above 90% between the prediction mean and actual/measured data. What is more interesting is that the confidence bound (i.e., 2 standard deviations from the mean prediction value) covers the actual data point, establishing that the application of GPR to perform mean prediction and confidence region prediction can provide a quantitative measure of uncertainty that a particular recipe will have if it is employed for fabrication.

As shown, the etching rate and the verticality of the sidewall angle can be predicted with more than 90% accuracy, providing a way to estimate the etching profile before starting the actual process in a clean-room, saving time, material, and man-power resources.

It is contemplated that this method is not limited to just one material or one specific process, but can be expanded to include other process, the only constraint being the data localization for ML model training.

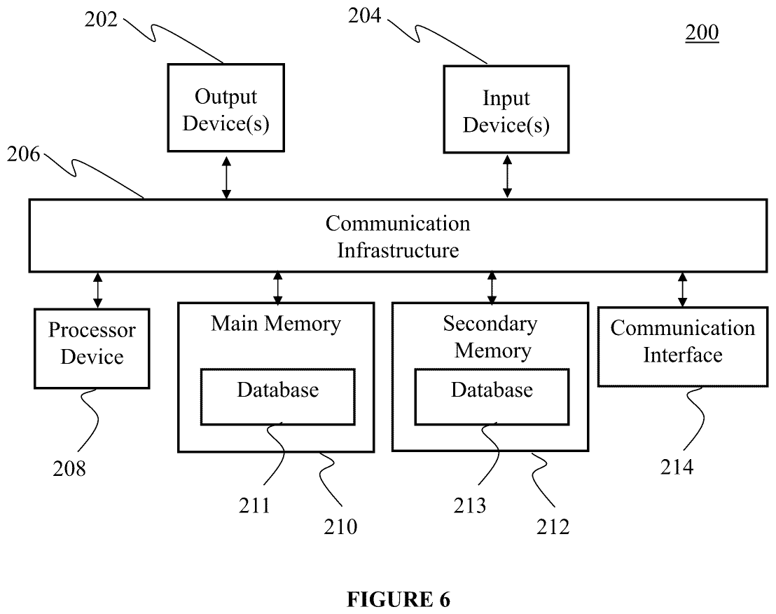

FIG. 6 illustrates exemplary computing components of any system, apparatus, or device that may be configured to implement the methods according to the invention.

One or more computing components 200 may carry out the methods presented herein as computer code.

Computing components 200 includes an input/output display interface 202 connected to communication infrastructure 204—such as a bus —, which forwards data such as graphics, text, and information from the communication infrastructure 204 or from a frame buffer (not shown) to other components 200. The input/output display interface 202 may be, for example, a keyboard, touch screen, joystick, trackball, mouse, monitor, speaker, printer, any other computer peripheral device, or any combination thereof, capable of entering and/or viewing data.

Computing components 200 includes one or more processors 206, which may be a special purpose or a general-purpose digital signal processor that processes certain information. Computing components 200 also includes a main memory 208, for example random access memory (RAM), read-only memory (ROM), mass storage device, or any combination thereof.

Computing components 200 may also include a secondary memory 210 such as a hard disk unit 212, a removable storage unit 214, or any combination thereof. Computing components 200 may also include a communication interface 216, for example, a modem, a network interface (such as an Ethernet card or Ethernet cable), a communication port, a PCMCIA slot and card, wired or wireless systems (such as Wi-Fi, Bluetooth, Infrared), local area networks, wide area networks, intranets, etc.

It is contemplated that the main memory 208, secondary memory 210, communication interface 216, or a combination thereof, function as a computer usable storage medium, otherwise referred to as a computer readable storage medium, to store and/or access computer software including computer instructions. For example, computer programs or other instructions may be loaded into the computing components 200 such as through a removable storage device, for example, a floppy disk, ZIP disk, magnetic tape, portable flash drive, optical disk such as a CD or DVD or Blu-ray, MEMS, or nanotechnological apparatus. Specifically, computer software including computer instructions may be transferred from the removable storage unit 214 or hard disc unit 212 to the secondary memory 210 or through the communication infrastructure 204 to the main memory 208 of the computing components 200.

Communication interface 216 allows software, instructions and data to be transferred between the computing components 200 and external devices or external networks. Software, instructions, and/or data transferred by the communication interface 216 are typically in the form of signals that may be electronic, electromagnetic, optical, or other signals capable of being sent and received by the communication interface 216. Signals may be sent and received using wire or cable, fiber optics, a phone line, a cellular phone link, a Radio Frequency (RF) link, wireless link, or other communication channels.

Computer programs, when executed, enable the computing components 200, particularly the processor 206, to implement the methods of the invention according to computer software including instructions.

The computing components 200 described herein may perform any one of, or any combination of, the steps of any of the methods presented herein. It is also contemplated that the methods according to the invention may be performed automatically, or may be invoked by some form of manual intervention.

The computing components 200 of FIG. 6 is provided only for purposes of illustration, such that the invention is not limited to this specific embodiment. It is appreciated that a person skilled in the relevant art knows how to program and implement the invention using any structure for a computing any system, apparatus, or device.

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure or system. Further, the terms and phrases used herein are not intended to be limiting, but rather to provide an understandable description of the invention.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above-described embodiments, methods, and examples, but by all embodiments and methods within the scope and spirit of the disclosure.

1. A method performed by a system, apparatus, or device, the method of using a machine learning based algorithm to calibrate simulation models for semiconductor devices, comprising the steps of:
(1) performing characterization on a semiconductor device, wherein simulation models of the semiconductor device need calibration; and
(2) establishing a data set for different optical characteristics and electrical characteristics of the semiconductor device.

2. The method of claim 1, wherein calibration parameters that are known with absolute values are excluded.

3. The method of claim 2, wherein the calibration parameters are measured data or data provided by a manufacturer of the semiconductor device.

4. The method of claim 1, wherein the semiconductor device is a photovoltaic device.

5. The method of claim 4, wherein the photovoltaic device is a piezoelectric thin-film material aluminum scandium nitride (AIScN).

6. A method performed by a system, apparatus, or device, the method of using a machine learning based algorithm to calibrate simulation models for a device, comprising the steps of:
(1) performing characterization on the device and its precursors to establish a data set for different optical characteristics and electrical characteristics of the device;
(2) assigning an initial value range for each input parameter that needs to be calibrated;
(3) using an uncalibrated simulation model to create one or more training data ranges for a machine learning model;
(4) using the initial value range of input data to make predictions;
(5) each prediction is compared against measurements to check if an accuracy exceeds a minimal threshold;
(6) determining if the accuracy reaches the minimal threshold, and if so, the input parameters of that particular prediction are declared as calibrated providing a calibrated simulation model;
(7) updating initial parameters with the best prediction data; and
(8) iteratively repeating steps (1)-(7).

7. The method of claim 6, wherein data generated from the calibrated simulation model is used as training data for developing digital twins of the device.

8. The method of claim 6, wherein the initial value range is assigned from literature or provided by the device manufacturer.

9. The method of claim 6, wherein the assigning step further comprises the step of excluding from the input parameters that are known with absolute values.

10. The method of claim 6, wherein the device is a photovoltaic device comprising a piezoelectric thin-film material aluminum scandium nitride (AIScN).

11. The method of claim 6, wherein the prediction is directed to and etching rate or vertical sidewall angle.

12. The method of claim 6, wherein the prediction is directed to characteristics of an etching process of a material.

13. The method of claim 6, wherein the material is selected from the group of Nitrades, ceramics and oxides.

14. The method of claim 6, wherein process parameters are used for input parameters.

15. The method of claim 6, wherein the using step further comprises Gaussian process regression.
